(19) United States
(12) Patent Application Publication
(10) Pub. No.: US 2006/0178010 A1
(43) Pub. Date: Aug. 10, 2006

(54) Member having plasma-resistance for semiconductor manufacturing apparatus and method for producing the same

(75) Inventors: Junichi Iwasawa, Fukuoka (JP); Hironori Hatono, Fukuoka (JP); Naoya Terada, Fukuoka (JP); Yuji Aso, Fukuoka (JP); Masakatsu Kiyohara, Fukuoka (JP)

Correspondence Address: CARRIER BLACKMAN AND ASSOCIATES, 24101 NOVI ROAD, SUITE 100, NOVI, MI, 48375, US

(73) Assignee: TOTO LTD., Fukuoka (JP)

(21) Appl. No.: 11/294,762

(22) Filed: Mar. 23, 2006

(30) Foreign Application Priority Data
Feb. 2, 2004 (JP) 2004-025262

(51) Int. Cl. C04B 35/48; H01L 21/302

(52) U.S. Cl. 438/710; 501/102

(57) ABSTRACT

In order to control and reduce generation of disjoined grains from a plasma-resistant member, the present invention provides a plasma-resistant member having no pores and boundary layers. In a layer structure made of yttria polycrystal and formed on a surface of a member for a semiconductor manufacturing apparatus on a side exposed to plasma, the ratio of pores to the surface of the layer structure is less than 0.1 area %. With this, corrosion from pores never progresses even in a plasma atmosphere. It is also possible to control and reduce disjoined grains due to such corrosion.

### BACKGROUND OF THE INVENTION

1. Field of the Invention

The present invention relates to a member having plasma-resistance for a semiconductor manufacturing apparatus and a method for producing the same. More specifically, the present invention relates to a member for a semiconductor manufacturing apparatus which has preferable plasma-resistance in an atmosphere of halogen-based corrosive gas.

2. Description of Prior Art

In a conventional member for a semiconductor manufacturing apparatus which needs plasma-resistance, a sintered body of alumina having high purity or a film on which yttria is thermally sprayed is used (Document 1).

However, there are pores or boundary layers of several to several tens of μm in a sintered body or a thermally-sprayed film. When exposed to a plasma atmosphere, corrosion progresses from the pores or the boundary layers, and the pores are enlarged or cracks are generated on the surface. Therefore, there is a drawback that disjoined grains due to the progress of the corrosion scatter within the semiconductor manufacturing apparatus and contaminate a semiconductor device, which causes the performance or the reliability of the semiconductor to be deteriorated, or the disjoined grains cut the surface of the member having plasma-resistance itself, which causes other grains to be disjoined.

Document 1: Japanese Patent Application Publication No. 2002-252209, page 2

The present invention was made to solve the above-mentioned problems. In order to control and reduce generation of disjoined grains from a plasma-resistant member, the object of the present invention is to provide a plasma-resistant member having no pores and boundary layers.

### SUMMARY OF THE INVENTION

In order to achieve the above-mentioned object, according to the present invention, in a layer structure made of yttria polycrystal and formed on a surface of a member for a semiconductor manufacturing apparatus on a side exposed to plasma, the ratio of pores to the surface of the layer structure is less than 0.1 area %. With this, corrosion from pores never progresses even in a plasma atmosphere. It is also possible to control and reduce disjoined grains due to such corrosion.

According to the present invention, in the layer structure made of yttria polycrystal and formed on a surface of a member for a semiconductor manufacturing apparatus on a side exposed to plasma, the height of the formed layer structure is 1 μm or more. With this, corrosion from pores never progresses even in a case of being exposed to a plasma atmosphere for a long period of time. It is also possible to control and reduce disjoined grains due to such corrosion.

According to the present invention, in the layer structure made of yttria polycrystal and formed on a surface of a member for a semiconductor manufacturing apparatus on a side exposed to plasma, substantially no hyaline boundary layer exists in the yttria polycrystal. With this, corrosion from a boundary layer never progresses even in a plasma atmosphere. It is also possible to control and reduce disjoined grains due to such corrosion.

According to the present invention, in the layer structure made of yttria polycrystal and formed on a surface of a member for a semiconductor manufacturing apparatus on a side exposed to plasma, the average crystal grain diameter of the yttria polycrystal is less than 70 nm. With this, it is possible to control and reduce disjoined grains even in a plasma atmosphere. Even if disjoined grains are generated, it is possible to reduce the size of the disjoined grains.

According to the present invention, in the layer structure made of yttria polycrystal and formed on a surface of a member for a semiconductor manufacturing apparatus on a side exposed to plasma, the average crystal grain diameter of the yttria polycrystal is less than 50 nm. With this, it is possible to control and reduce disjoined grains even in a plasma atmosphere. Even if disjoined grains are generated, it is possible to reduce the size of the disjoined grains.

According to the present invention, in the layer structure made of yttria polycrystal and formed on a surface of a member for a semiconductor manufacturing apparatus on a side exposed to plasma, the average crystal grain diameter of the yttria polycrystal is less than 30 nm. With this, it is possible to control and reduce disjoined grains even in a plasma atmosphere. Even if disjoined grains are generated, it is possible to reduce the size of the disjoined grains.

According to the present invention, part of the yttria polycrystal of the layer structure is bonded directly to a substrate surface by forming an anchor section. With this, it is possible to increase the bonding strength between the substrate and the layer structure, so as to control and reduce disjoined grains even in a plasma atmosphere.

### BRIEF DESCRIPTION OF THE DRAWINGS

FIG. 1 is a photograph of a surface of a layer structure made of yttria polycrystal according to the present invention with a scanning electron microscope before plasma exposure;

FIG. 2 is a photograph of a surface of a layer structure made of yttria polycrystal according to the present invention with a scanning electron microscope after plasma exposure;

FIG. 3 is a photograph of a surface of a thermally-sprayed film of yttria with a scanning electron microscope before plasma exposure;

FIG. 4 is a photograph of a surface of a thermally-sprayed film of yttria with a scanning electron microscope after plasma exposure;

FIG. 5 is a photograph of a surface of a sintered body of yttria (processed by HIP) with a scanning electron microscope before plasma exposure;

FIG. 6 is a photograph of a surface of a sintered body of yttria (processed by HIP) with a scanning electron microscope after plasma exposure; and

FIG. 7 is a schematic diagram of an apparatus for producing a layer structure made of yttria polycrystal according to the present invention.

### DETAILED DESCRIPTION OF PREFERRED EMBODIMENTS

The terms used in the present invention are defined as follows:

Polycrystal

The term “polycrystal” means a structure formed by joining and integrating crystallites. Each crystallite forms a crystal substantially by itself, and the diameter thereof is usually 5 nm or more. There is some possibility that fine particles exist in the structure without being fractured, but they are substantially polycrystalline.

Pore Ratio

The term “pore ratio” means a value shown by an area percentage of the area of pores which is measured and computed using an image processing software (Image-Pro PLUS manufactured by Media Cybernetics, Inc.) with respect to a predetermined area of a sample surface which is observed using a scanning electron microscope (S4100 manufactured by Hitachi, Ltd.) and whose image is digitized.

Formation Height

The term “formation height” means a value measured by using a stylus surface profiler: Dectak 3030 manufactured by ULVAC, Inc.

Boundary Face

The term “boundary face” means an area where a boundary is formed between crystallites.

Boundary Layer

The term “boundary layer” means a layer which has a certain thickness (usually several nm to several μm) in a boundary face or a grain boundary which is referred to in a sintered body. The boundary layer usually has an amorphous structure that is different from a crystal structure within a crystal grain. In some cases, it includes segregation of impurities.

Average Crystal Grain Diameter

The term “average crystal grain diameter” means the size of a crystallite computed by a method of Scherrer in an X-ray diffraction method. In the present invention, the sizes were measured and computed using MXP-18 manufactured by MAC Science Co., Ltd.

Anchor Section

The term “anchor section” means an irregularity formed on the boundary between a substrate and a brittle material structure. In particular, the irregularity is not formed on the substrate in advance, but formed by changing surface precision of the original substrate when a brittle material structure is formed.

Fine Particle

The term “fine particle” means particles whose average diameter is 5 μm or less which is identified by granular variation measurement or a scanning electron microscope in a case where a primary particle is dense. On the other hand, in a case where a primary particle is porous which is easy to fracture by impact, it means particles whose average diameter is 50 μm or less. Powder means a state where these fine particles naturally aggregate.

Aerosol

The term “aerosol” means one in which the above-mentioned fine particles are scattered in gas such as helium, nitrogen, argon, oxygen, dried air, or mixed gas thereof. Preferably, primary particles are scattered. However, an aggregate of primary particles is usually contained.

Normal Temperature

The term “normal temperature” means a significantly low temperature with respect to the temperature for sintering ceramics. This is substantially a room temperature atmosphere of 0-100° C.

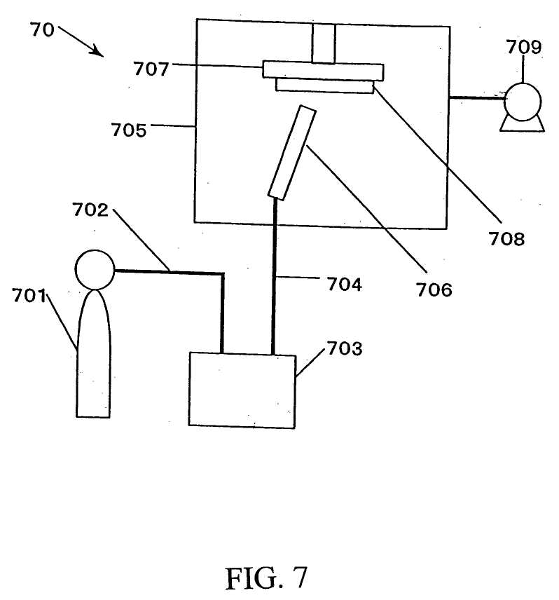

Next, preferred embodiments according to the present invention will be explained. First, a method for producing a layer structure made of yttria polycrystal on a substrate will be explained with reference to FIG. 7. In a producing apparatus 70 shown in FIG. 7, a gas tank 701 is connected to an aerosol generator 703 for containing yttria particles of 0.01-5 μm via a gas pipe 702. The aerosol generator 703 is connected to a nozzle 706 having an opening of 0.4 mm in length and 20 mm in width, which is provided within a forming chamber 705, via an aerosol carrier pipe 704. A substrate 708 mounted on an XY stage 707 is provided above the nozzle 706. The forming chamber 705 is connected to a vacuum pump 709.

Next, producing processes using the producing apparatus 70 having the above-mentioned structure will be explained. The gas tank 701 is opened and gas is introduced to the aerosol generator 703 via the gas carrier pipe 702, so as to generate aerosol containing yttria particles. The aerosol is sent to the nozzle 706 via the carrier pipe 704, and ejected from the opening of the nozzle 706 at a high speed. In this instance, the inside of the forming chamber 705 is adjusted to be a pressure-reducing atmosphere of several kPa by activating the vacuum pump 709.

The yttria particles are caused to collide with the substrate provided above the opening of the nozzle 706 at a high speed, and fractured or deformed, so that particles or chips are bonded to each other. In this way, a layer structure made of yttria polycrystal is formed on the substrate. Since the substrate 708 is oscillated by the XY stage 707, the shape or the area of the layer structure made of yttria polycrystal is adjusted to be a preferable one. The above process is performed in a normal temperature atmosphere.

A more preferable method for producing a layer structure made of yttria polycrystal on a substrate will be explained.

The gas filled in the gas tank 701 may be helium, nitrogen, argon, oxygen, dried air, or mixed gas thereof. However, helium or nitrogen is used in the more preferable method.

Also, the yttria particles contained in the aerosol generator 703 have an average diameter of 0.1-5 μm in the more preferable method.

The layer structure made of yttria polycrystal produced by using the above-mentioned producing apparatus 70 can be used as a member for a semiconductor manufacturing apparatus which is exposed to a plasma atmosphere such as a chamber, a bell jar, a susceptor, a clamp ring, a focus ring, a shadow ring, an insulating ring, a dummy wafer, a tube for generating high-frequency plasma, a dome for generating high-frequency plasma, a high-frequency transmitting window, a infrared transmitting window, a monitor window, a lift pin for supporting a semiconductor wafer, a shower plate, a baffle plate, a bellows cover, an upper electrode or a lower electrode. As a substrate of the member for a semiconductor manufacturing apparatus, metal, ceramics, semiconductor, glass, quartz, resin or the like can be used. Also, the layer structure made of yttria polycrystal according to the present invention can be used as an electrostatic chuck for an etching apparatus which performs fine processing to a semiconductor wafer or the like.

Next, preferred embodiments according to the present invention will be explained with reference to examples.

### Example 1

Yttria particles having an average diameter of 0.4 μm were filled in the aerosol generator 703 of the producing apparatus 70, and helium gas at a flow rate of 7 L/min was used as carrier gas. A layer structure made of yttria polycrystal having a height of 20 μm and an area of 20×20 mm was formed on an aluminum substrate.

The pore ratio of the surfaces of the yttria polycrystal, a thermally-sprayed film of yttria, and a sintered body of yttria (processed by HIP) were measured. In order to measure the pore ratio, the surface of the sample was observed by a scanning electron microscope (S4100 manufactured by Hitachi, Ltd.), the image was digitized, and the pore ratio of the sample surface was computed using an image processing software (Image-Pro PLUS manufactured by Media Cybernetics, Inc.). The area of the sample surface to be observed was set to be 318 μm×468 μm. The results are shown in Table 1. The pore ratio of the yttria polycrystal according to the present invention was very small compared to the thermally-sprayed film of yttria, and the sintered body of yttria which had undergone HIP processing so as to reduce the pores.

TABLE 1

| | Yttria | Thermally- | Sintered body of |
|---|---|---|---|
| | polycrystal according | sprayed film | yttria (processed by |
| Sample | to the present invention | of yttria | HIP) |
| Pore ratio | 0.05 | 7.9 | 1.1 |
| (area %) | | | |

In order to evaluate plasma-resistance, the yttria polycrystal produced according to the present invention, the thermally-sprayed film of yttria, and the sintered body of yttria (processed by HIP) were exposed to a plasma atmosphere by using an RIE-type etcher apparatus (DEA-506 manufactured by NEC ANELVA CORPORATION) and CF₄+O₂ as corrosive gas with an output of microwaves of 1 kW for a period of time for irradiation of 180 minutes. In this instance, part of each sample was masked with a silicon wafer.

After the samples were exposed to a plasma atmosphere, the height difference between the masked area and the non-masked area of each sample was measured by using a stylus surface profiler (Dectak 3030 manufactured by ULVAC, Inc), and plasma-resistance was evaluated based on the height difference.

The results are shown in Table 2. The corrosion depth of the yttria polycrystal according to the present invention was 261 nm, the corrosion depth of the thermally-sprayed film of yttria was 443 nm, and the corrosion depth of the sintered body of yttria (processed by HIP) was 339 nm. The yttria polycrystal according to the present invention has excellent plasma-resistance.

TABLE 2

| | Yttria | Thermally- | Sintered body of |
|---|---|---|---|
| | polycrystal according | sprayed film | yttria (processed |
| Sample | to the present invention | of yttria | by HIP) |
| Corrosion | 261 | 443 | 339 |
| depth (nm) | | | |

The surfaces of the yttria polycrystal, the thermally-sprayed film of yttria, and the sintered body of yttria (processed by HIP) were observed by a scanning electron microscope (S4100 manufactured by Hitachi, Ltd.) before and after plasma exposure.

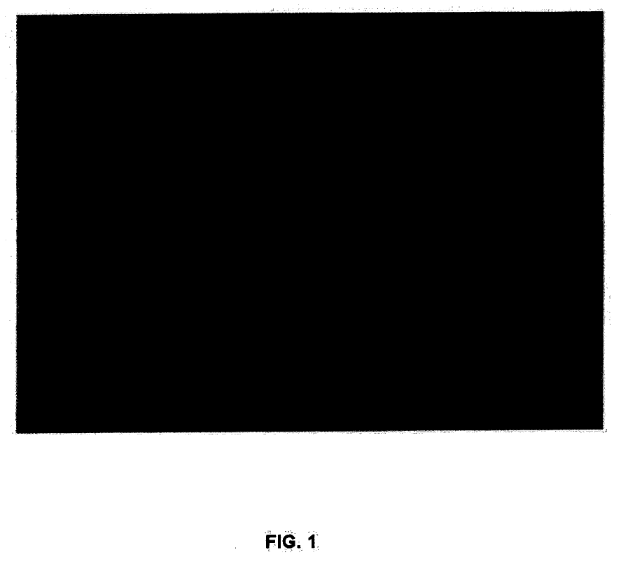

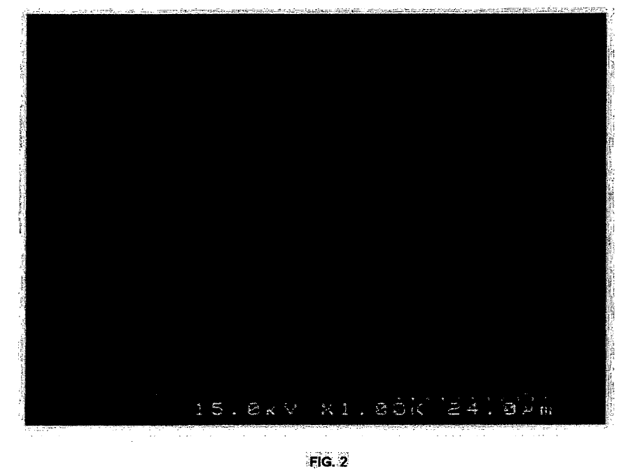

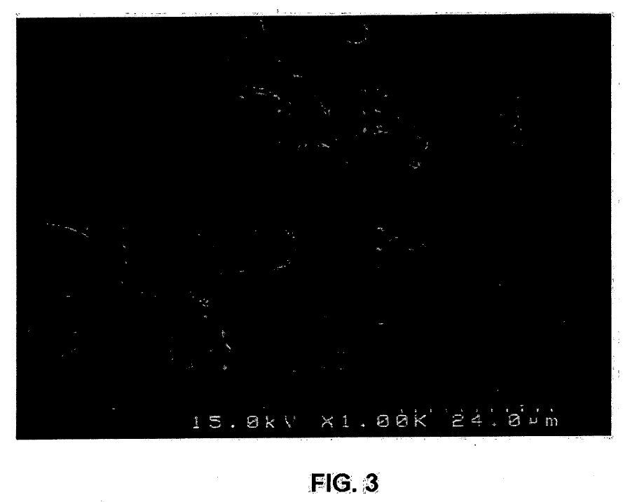

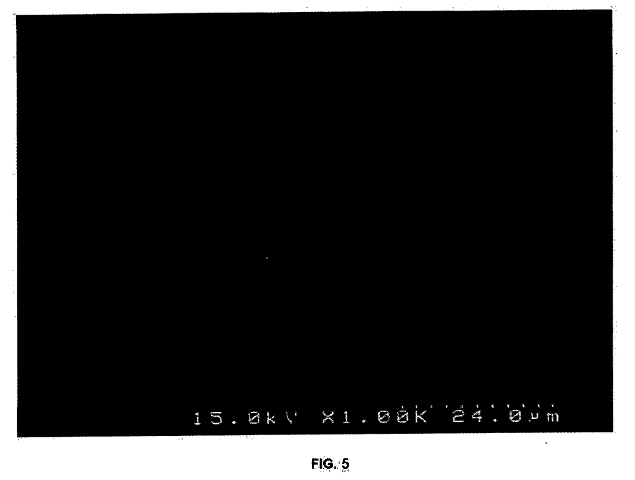

The surface of the yttria polycrystal according to the present invention had no pores before plasma exposure (FIG. 1), while the surface of the thermally-sprayed film of yttria (FIG. 3) and the surface of the sintered body of yttria (processed by HIP) (FIG. 5) had pores of several μm. After being exposed to plasma, the surface of the yttria polycrystal according to the present invention was not changed as shown in FIG. 2.

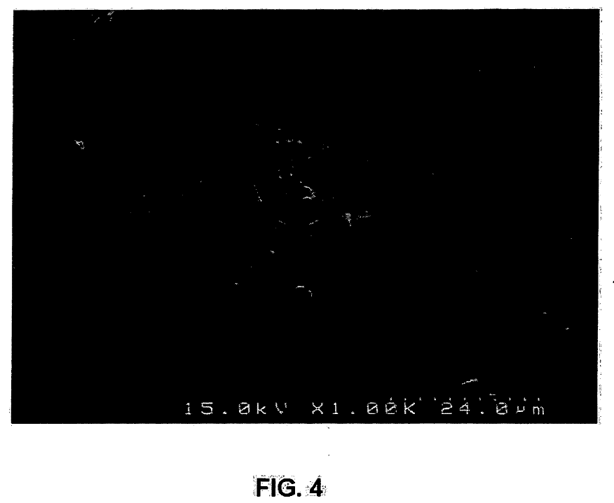

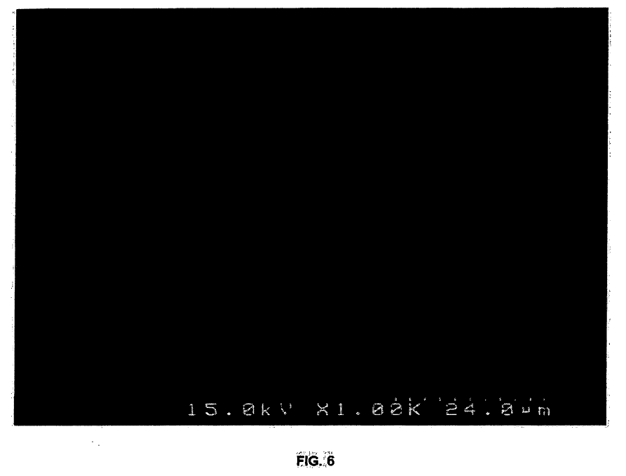

On the other hand, the surface of the thermally-sprayed film of yttria was changed to a state of being cracked after being exposed to plasma as shown FIG. 4. As for the surface of the sintered body of yttria (processed by HIP) after being exposed to plasma, corrosion occurred around the pores which had already existed before plasma exposure, which caused the pores to be enlarged, as shown FIG. 6.

### Example 2

Yttria particles having an average diameter of 0.4 μm were filled in the aerosol generator 703 of the producing apparatus 70, and high-purity nitrogen gas at a flow rate of 7 L/min was used as carrier gas. A layer structure made of yttria polycrystal having a height of 40 μm and an area of 20×20 mm was formed on an aluminum substrate.

The average crystal grain diameter of the yttria polycrystal was measured and computed by a method of Scherrer in an X-ray diffraction method (MXP-18, XPRESS manufactured by MAC Science Co., Ltd.). In comparison, the average crystal grain diameter of a thermally-sprayed film of yttria and a sintered body of yttria (processed by HIP) were also measured.

The results are shown in Table 3. The average crystal grain diameter of the yttria polycrystal according to the present invention is 19.2, which is smaller than that of the thermally-sprayed film of yttria or the sintered body of yttria (processed by HIP), and the yttria polycrystal according to the present invention is made of very small crystals.

TABLE 3

| | Yttria | Thermally- | Sintered body of |
|---|---|---|---|
| | polycrystal according | sprayed film | yttria (processed by |
| Sample | to the present invention | of yttria | HIP) |
| Average | 19.2 | 70.5 | 217.6 |
| crystal | | | |
| grain | | | |
| diameter | | | |
| (nm) | | | |

As is explained in the above, according to the present invention, it is possible to control and reduce generation of disjoined grains in a member for a semiconductor manufacturing apparatus which is exposed to a plasma atmosphere.

1. A member for a semiconductor manufacturing apparatus which requires plasma-resistance comprising a layer structure made of yttria polycrystal which is formed at least on a side exposed to plasma, wherein the ratio of pores to the surface of the layer structure is less than 0.1 area %.

2. The member for a semiconductor manufacturing apparatus according to claim 1, wherein the height of the formed layer structure is 1 μm or more.

3. The member for a semiconductor manufacturing apparatus according to claim 1, wherein substantially no hyaline boundary layer exists on a boundary face between crystals forming the yttria polycrystal.

4. The member for a semiconductor manufacturing apparatus according to claim 1, wherein the average crystal grain diameter of the yttria polycrystal is less than 70 nm.

5. The member for a semiconductor manufacturing apparatus according to claim 1, wherein the average crystal grain diameter of the yttria polycrystal is less than 50 nm.

6. The member for a semiconductor manufacturing apparatus according to claim 1, wherein the average crystal grain diameter of the yttria polycrystal is less than 30 nm.

7. The member for a semiconductor manufacturing apparatus according to claim 1, wherein an anchor section is formed on a surface of a substrate by biting part of the yttria polycrystal into the surface of the substrate.

8. A method for producing a member for a semiconductor manufacturing apparatus involving use of plasma comprising the steps of:
generating aerosol in which yttria particles are scattered in gas;
ejecting the aerosol from a nozzle toward a substrate;
causing the aerosol to collide with a surface of the substrate; and
fracturing or deforming the yttria particles due to the impact of the collision, so that the particles are bonded to each other, thereby
forming yttria polycrystal on the substrate.

9. The method for producing a member for a semiconductor manufacturing apparatus according to claim 8, wherein the step of forming yttria polycrystal is performed at a normal temperature.

10. The member for a semiconductor manufacturing apparatus according to claim 2, wherein an anchor section is formed on a surface of a substrate by biting part of the yttria polycrystal into the surface of the substrate.

11. The member for a semiconductor manufacturing apparatus according to claim 3, wherein an anchor section is formed on a surface of a substrate by biting part of the yttria polycrystal into the surface of the substrate.

12. The member for a semiconductor manufacturing apparatus according to claim 6, wherein an anchor section is formed on a surface of a substrate by biting part of the yttria polycrystal into the surface of the substrate.

13. The method for producing a member for a semiconductor manufacturing apparatus according to claim 8, wherein the wherein the ratio of pores to the surface of the yttria polycrystal is less than 0.1 area %.

14. The method for producing a member for a semiconductor manufacturing apparatus according to claim 8, wherein the height of the formed yttria polycrystal is 1 μm or more.

15. The method for producing a member for a semiconductor manufacturing apparatus according to claim 8, wherein substantially no hyaline boundary layer exists on a boundary face between crystals forming the yttria polycrystal.

16. The method for producing a member for a semiconductor manufacturing apparatus according to claim 8, wherein the average crystal grain diameter of the yttria polycrystal is less than 30 nm.

17. The method for producing a member for a semiconductor manufacturing apparatus according to claim 8, wherein the step of causing the aerosol to collide with the surface of the substrate forms an anchor section on the surface by biting part of the yttria polycrystal into the surface of the substrate.
